(19) United States
(12) Patent Application Publication
(10) Pub. No.: US 2015/0372046 A1
(43) Pub. Date: Dec. 24, 2015

(54) A NOVEL IR IMAGE SENSOR USING A SOLUTION-PROCESSED PbS PHOTODETECTOR

(71) Applicant: University of Florida Research Foundation, Inc., Gainesville, FL (US)

(72) Inventors: Do Young Kim, Jenks, OK (US); Franky So, Cary, NC (US); Jae Woong Lee, Raleigh, NC (US)

(73) Assignee: University of Florida Research Foundation, Inc., Gainesville, FL (US)

(21) Appl. No.: 14/763,394

(22) PCT Filed: Jan. 23, 2014
(86) PCT No.: PCT/US2014/012722

§ 371 Date: Jul. 24, 2015

Related U.S. Application Data
(60) Provisional application No. 61/756,730, filed on Jan. 25, 2013.

(51) Int. Cl. H01L 27/146; H01L 27/28

(52) U.S. Cl. CPC H01L 27/14649; H01L 27/283

(57) ABSTRACT

An image sensor is constructed on a substrate that is a read-out transistor array with a multilayer array of infrared photodetectors formed thereon. The infrared photodetectors include a multiplicity of layers including an infrared transparent electrode distal to the substrate, a counter electrode directly contacting the substrate, and an infrared sensitizing layer that comprises a multiplicity of nanoparticles. The layers can be inorganic or organic materials. In addition to the electrodes and sensitizing layers, the multilayer stack can include a hole-blocking layer, an electron-blocking layer, and an anti-reflective layer. The infrared sensitizing layer can be PbS or PbSe quantum dots.

### CROSS-REFERENCE TO RELATED APPLICATION

The present application claims the benefit of U.S. Provisional Application Ser. No. 61/756,730, filed Jan. 25, 2013, which is hereby incorporated by reference herein in its entirety, including any figures, tables, or drawings.

### BACKGROUND OF INVENTION

Infrared photodetectors are devices that detect infrared radiation. A significant quantity of research has been performed on these devices due to their potential applications in night vision, range finding, security, and semiconductor wafer inspections. Recently a photodetector employing quantum dots (QDs) as the photoactive material has been disclosed in Koch et al., U.S. Pat. No. 6,906,326, where InAs in GaAs QDs, and are employed in an all inorganic photodetector prepared by conventional epi growth processes are connected to a read-out circuit by bump bonding to the read-out circuit and assembled into an array.

QDs are crystalline nanoparticles, typically, of a III-V semiconducting material, for example, InAs/GaAs. QDs have a 3-d localized attractive potential where electrons are confined in the QD having dimensions on the electron wavelength, having discrete energy levels. By controlling the size of the QD, sensitivity to a specific wavelength of light is achieved. Photons incident on the QDs are absorbed when the photon's wavelength is of an energy difference between the ground state and, generally, the first excited state of the quantum dot. When an electric field is applied to the QDs, current flows when the QDs are in their excited state, which permits detection of light at the wavelength(s) that promote the electron's excitation.

There remains a need for performance- and cost-effective quantum dot infrared photodetectors (QDIPs) for image sensor applications, where one or more wavelengths are detected simultaneously.

### BRIEF SUMMARY

Embodiments of the invention are directed to an image sensor comprising an infrared photodetector array where the sensitizing layer of the photodetector comprises nanoparticles. The IR photodetector array can be a quantum dot infrared photodetector array (QDIPA) where the sensitizing layer comprises PbS or PbSe quantum dots. The IR photodetector has an IR transparent electrode. Additionally, the IR photodetector includes a counter electrode, and can include a hole-blocking layer, an electron-blocking layer, and/or an antireflective layer to enhance performance of the image sensor.

### BRIEF DESCRIPTION OF DRAWINGS

FIG. 1 shows a drawing of an image sensor where a quantum dot infrared photodetector array (QDIPA) comprising an array of quantum dot infrared photodetectors (QDIPs) is constructed on a substrate of a CMOS read-out transistor array, according to an embodiment of the invention.

FIG. 2 shows a drawing of a cross section view of the QDIPA deposited on a conventional transistor read-out array, according to an embodiment of the invention.

FIG. 3 shows a plot of transmittance vs. IR wavelength for a Ca/Ag bilayer electrode, which can be employed as the top electrode of the QDIPs of the QDIPA, according to an embodiment of the invention.

FIG. 4 shows over-laid plots of absorbance in the IR for PbSe QDs of different sizes that can be used as the IR sensitizing layer of QDIPs in the image sensors, according to embodiments of the invention.

FIG. 5 shows an inorganic-organic QDIP with ITO and Ca/Ag transparent electrodes and PbS QDs as the IR sensitizing layer, for comparison of the quality of detection through different electrodes, for use in an image sensor, according to an embodiment of the invention.

FIG. 6 is a plot of the I-V characteristics of the device of FIG. 5 upon illumination through both transparent faces of the QDIP for use in an image sensor, according to an embodiment of the invention.

FIG. 7 is a plot of the EQE characteristics of the device of FIG. 5 upon illumination through both transparent faces of the QDIP for use in an image sensor, according to an embodiment of the invention.

FIG. 8 is a plot of the detectivity characteristics of the device of FIG. 5 upon illumination through both transparent faces of the QDIP for use in an image sensor, according to an embodiment of the invention.

### DETAILED DISCLOSURE

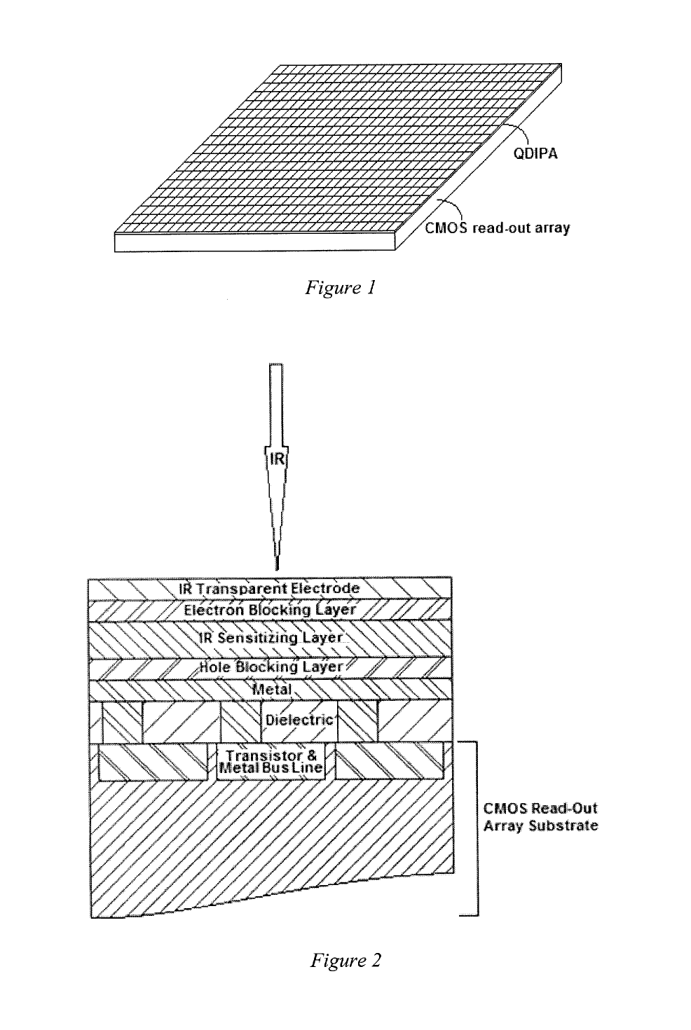

An embodiment of the invention is a quantum dot infrared photodetector array (QDIPA) that functions as an image sensor. Another embodiment of the invention is a method of fabricating the image sensor where the substrate for the quantum dot infrared photodetector is a read-out transistor. As illustrated in FIG. 1, the QDIPA is an assembly of organic or inorganic nanoparticle photodetectors connected in series with a conventional transistor based read-out array. An exemplary quantum dot infrared photodetector (QDIP) of the QDIPA is shown in FIG. 2.

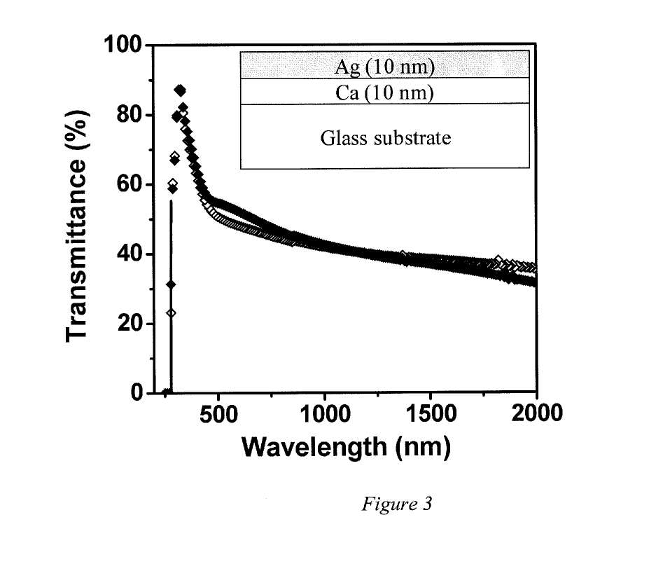

The QDIP includes a transparent electrode on the IR receiving face, where, in an exemplary embodiment of the invention, the transparent electrode can be a Ca (10 nm)/Ag (10 nm) bilayer. A Ca (10 nm)/Ag (10 nm) bilayer, as shown in the insert of FIG. 3, was tested with respect to its transparency to IR radiation, as indicated in the plot of FIG. 3, where the transmittance is about 40% at 2000 nm. The thickness of the Ca layer can be 5 to 50 nm and the thickness of the Ag layer can be 5 to 30 nm. Alternatively, the IR transparent electrode can be indium tin oxide (ITO), indium zinc oxide (IZO), aluminum tin oxide (ATO), aluminum zinc oxide (AZO), carbon nanotubes, silver nanowires, or an Mg:Al mixed layer with a Mg:Al composition ratio of 10:1 and a total thickness of 10 to 30 nm. The Mg:Al mixed layer can be employed with an additional tris-(8-hydroxy quinoline) aluminum (Alq₃) layer of up to 100 nm on the exterior face of the electrode, which acts as an anti-reflective layer. The IR sensitizing layer includes nanoparticles. In an embodiment of the invention, the nanoparticles can be quantum dots such as PbS QDs or PbSe QDs. The QDs can be of a single size or can be a plurality of sizes. The QDs can be of a single chemical composition or a plurality of compositions. In other embodiments of the invention, the nanoparticles are included as tin (II) phthalocyanine (SnPc) with C₆₀ (SnPc:C₆₀), aluminum phthalocyanine chloride (AlPcCl) with C₆₀ (AlPcCl:C₆₀) or titanyl phthalocyanine (TiOPc) with C₆₀ (TiOPc:C₆₀).

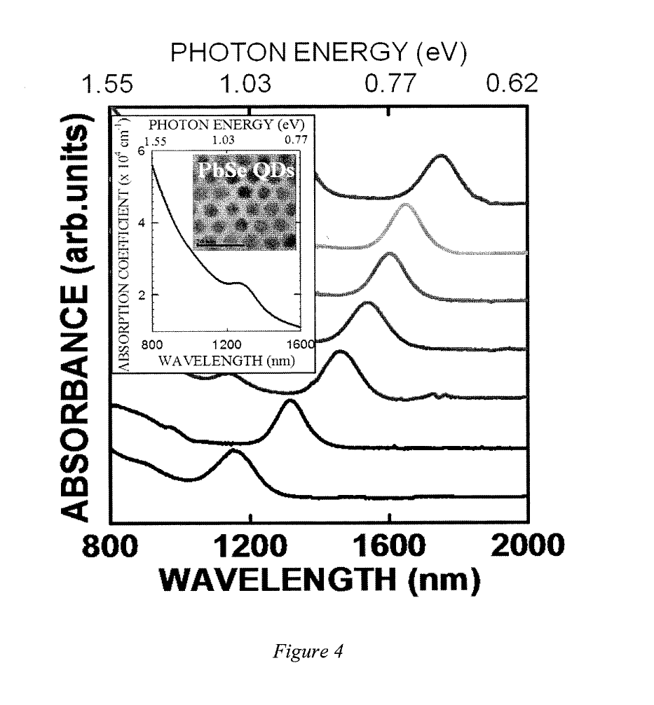

In an exemplary embodiment of the invention, the IR sensitizing layer can be PbS QDs that can be of any size or mixture of sizes such that the wavelength of absorption by the QDs is any portion of the spectrum from 0.7 μm to 2.0 μm. In like manner, as shown in FIG. 4, PbSe QDs can be prepared that display absorption over any portion of the near IR spectrum.

Adjacent to an electrode of the QDIP can reside an electron-blocking layer (EBL). The EBL can be poly(9,9-dioctyl-fluorene-co-N-(4-butylphenyl)diphenylamine) (TFB), 1,1-bis[(di-4-tolylamino)phenyl] cyclohexane (TAPC), N,N′-diphenyl-N,N′(2-naphthyl)-(1,1′-phenyl)-4,4′-diamine (NPB), N,N′-diphenyl-N,N′-di(m-tolyl) benzidine (TPD), Poly-N,N-bis-4-butylphenyl-N,N-bis-phenylbenzidine (poly-TPD), polystyrene-N,N-diphenyl-N,N-bis(4-n-butylphenyl)-(1,10-biphenyl)-4,4-diamine-perfluorocyclobutane (PS-TPD-PFCB), or any other EBL material. The electron-blocking layer (EBL) can be an inorganic EBL comprising, for example, NiO and can be a film of nanoparticles.

Adjacent to an electrode of the QDIP can be a hole-blocking layer (HBL). The HBL can be an organic HBL comprising, for example, 2,9-Dimethyl-4,7-diphenyl-1,10-phenanthroline (BCP), p-bis(triphenylsilyl)benzene (UGH2), 4,7-diphenyl-1,10-phenanthroline (BPhen), tris-(8-hydroxy quinoline) aluminum (Alq3), 3,5′-N,N′-dicarbazole-benzene (mCP), C₆₀, or tris[3-(3-pyridyl)-mesityl]borane (3TPYMB). The hole-blocking layer (HBL) can be an inorganic HBL comprising, for example, ZnO or TiO2 and can be a film of nanoparticles.

A counter electrode to the IR transparent electrode is constructed on the surface of the read-out transistor array that comprises the substrate of the image sensor. The counter electrode can be IR transparent, IR semitransparent, or IR opaque. The counter electrode can be an ITO, IZO, ATO, AZO, carbon nanotubes, Ag, Al, Au, Mo, W, or Cr. The read out array can be a Si transistor based read-out array, an oxide transistor based read-out array, or an organic transistor based read-out array. The read-out array can be a CMOS read-out array, an a-Si:H TFT array, a poly-Si TFT array or any other Si transistor read-out array. The read-out array can be a ZnO TFT read-out array, a GIZO TFT array, an IZO TFT array, or any other oxide transistor read-out array. The read-out array can be a pentacene TFT read-out array, a P3HT TFT array, a DNTT TFT array or any other organic transistor read-out array.

### METHODS AND MATERIALS

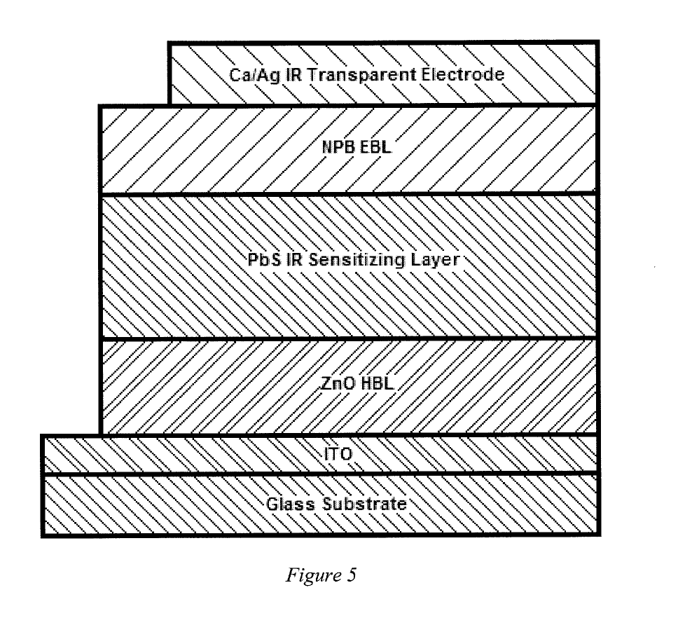

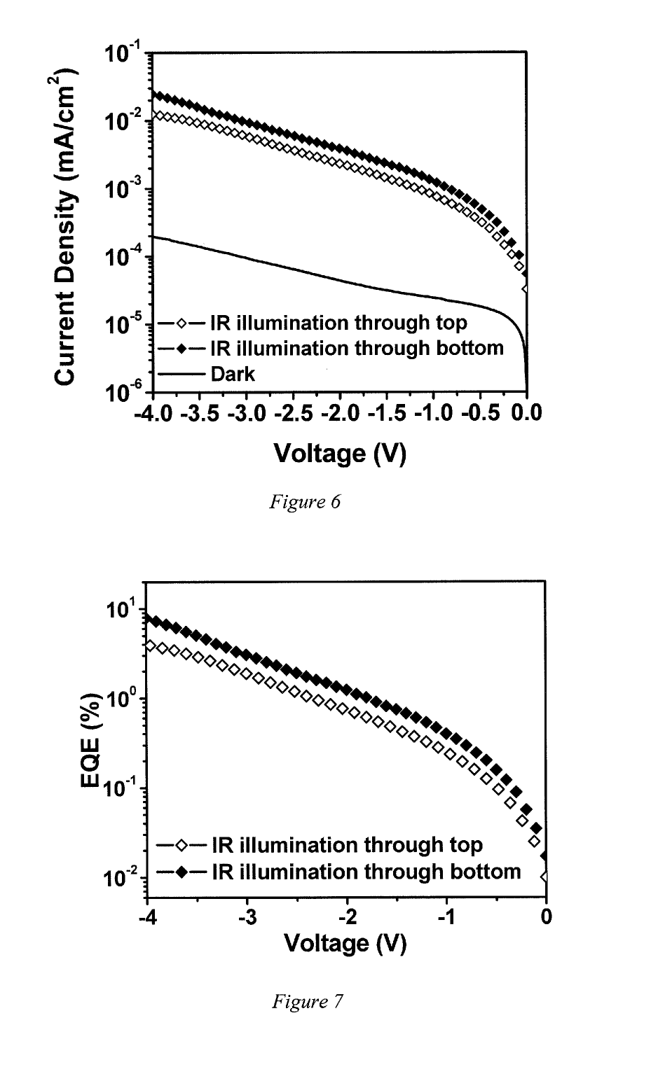

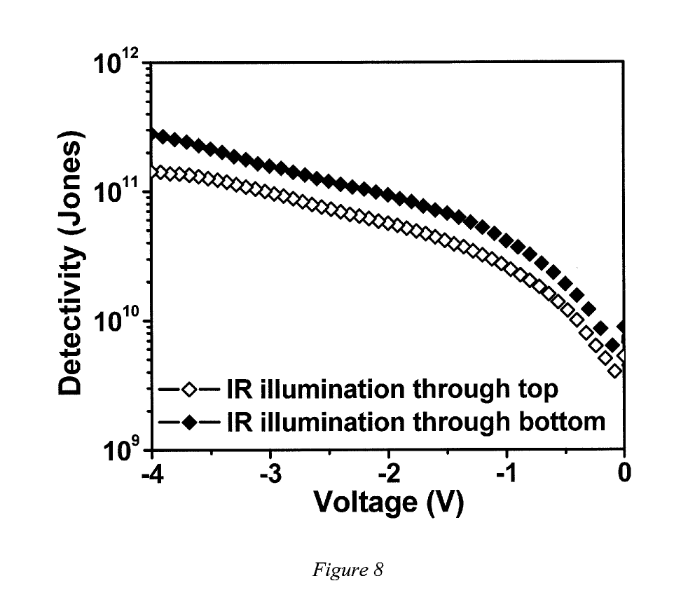

A QDIP was constructed on a glass substrate, with the structure shown in FIG. 5, to test the performance of a device with a Ca/Ag IR transparent electrode and a PbS QD IR sensitizing layer. FIG. 6 shows the I-V characteristics of the IR photodetector with IR transparent top electrode in dark and upon IR illumination. The current density in the dark was measured at about 1×10⁻⁴ mA/cm² at −3 V from the bottom (glass face) and the top (Ca/Ag) faces of the QDIP. Upon illumination with 1.2 μm IR, an increase in current density occurs to about 1×10⁻² mA/cm², or about two orders of magnitude. As shown in FIGS. 7 and 8, the EQE and detectivity of the IR photodetector with IR transparent top electrode are 4% and 1.5×10⁻¹¹ Jones at −4 V, respectively, under IR illumination through the Ca/Ag top electrode. The small difference in the quantities of illumination, EQE and detectivity through the Ca/Ag electrode and the ITO electrode allows the organic device to be fabricated by deposition of the Ca/Ag electrode directly on an organic EBL of the device.

It should be understood that the examples and embodiments described herein are for illustrative purposes only and that various modifications or changes in light thereof will be suggested to persons skilled in the art and are to be included within the spirit and purview of this application.

We claim:

1. An image sensor, comprising:
a substrate comprising a read-out transistor array; and
an array of infrared photodetectors, comprising an infrared transparent electrode distal to the substrate, a counter electrode directly contacting the substrate, and an infrared sensitizing layer comprising a multiplicity of nanoparticles.

2. The image sensor of claim 1, wherein the infrared transparent electrode comprises Ca/Ag bilayer, indium tin oxide (ITO), indium zinc oxide (IZO), aluminum tin oxide (ATO), aluminum zinc oxide (AZO), carbon nanotubes, silver nanowires, or an Mg:Al mixed layer.

3. The image sensor of claim 1, wherein the nanoparticles comprise PbS quantum dots, PbSe quantum dots, PbSSe quantum dots, tin (II) phthalocyanine (SnPc) with C₆₀ (SnPc:C₆₀), aluminum phthalocyanine chloride (AlPcCl) with C₆₀ (AlPcCl:C₆₀) or titanyl phthalocyanine (TiOPc) with C₆₀ (TiOPc:C₆₀).

4. The image sensor of claim 1, wherein the nanoparticles comprise PbS quantum dots and/or PbSe quantum dots.

5. The image sensor of claim 1, wherein the counter electrode comprises ITO, IZO, ATO, AZO, carbon nanotubes, Ag, Al, Au, Mo, W, or Cr.

6. The image sensor of claim 1, wherein the array of infrared photodetectors further comprises an electron-blocking layer (EBL).

7. The image sensor of claim 6, wherein the EBL comprises poly(9,9-dioctyl-fluorenc-co-N-(4-butylphenyl)diphenylamine) (TFB), 1,1 -bis[(di-4-tolylamino)phenyl] cyclohexane (TAPC), N,N′-diphenyl-N,N′(2-naphthyl)-(1,1′-phenyl)-4,4′-diamine (NPB), N,N′-diphenyl-N, N′-di(m-tolyl) benzidine (TPD), Poly-N,N-bis-4-butylphenyl-N,N-bis-phenylbenzidine (poly-TPD), polystyrene-N,N-diphenyl-N,N-bis(4-n-butylphenyl)-(1,10-biphenyl)-4,4-diamine-perfluorocyclobutane (PS-TPD-PFCB), and/or NiO.

8. The image sensor of claim 1, wherein the array of infrared photodetectors further comprises a hole-blocking layer (HBL)

9. The image sensor of claim 8, wherein the HBL comprises 2,9-Dimethyl-4,7-diphenyl-1,10-phenanthroline (BCP), p-bis(triphenylsilyl)benzene (UGH2), 4,7-diphenyl-1,10-phenanthroline (BPhen), tris-(8-hydroxy quinoline) aluminum (Alq3), 3,5′-N,N′-dicarbazole-benzene (mCP), C₆₀, tris[3-(3-pyridyl)-mesityl]borane (3TPYMB), ZnO and/or TiO₂.

10. The image sensor of claim 1, further comprising an anti-reflective layer on the exterior of the infrared transparent electrode.

11. The image sensor of claim 10, wherein the anti-reflective layer comprises an Alq₃, MoO₃, and/or TeO₂.

12. The image sensor of claim 1, wherein the read-out transistor array comprises a Si transistor based read-out array, an oxide transistor based read-out array, or an organic transistor based read-out array.

13. The image sensor of claim 1, wherein the read-out transistor array comprises a CMOS read-out array, an a-Si:H TFT array, or a poly-Si TFT array.

14. The image sensor of claim 1, wherein the read-out transistor array comprises a ZnO TFT read-out array, a GIZO TFT array, or an IZO TFT array.

15. The image sensor of claim 1, wherein the read-out transistor array comprises a pentacene TFT read-out array, a P3HT TFT array, or a DNTT TFT array.
